(19) United States
(12) Patent Application Publication
(10) Pub. No.: US 2015/0295320 A1
(43) Pub. Date: Oct. 15, 2015

(54) MODIFIED FOLDED DIPOLE ANTENNA ARRANGEMENT

(71) Applicant: New York University, New York, NY (US)

(72) Inventors: WONJE LEE, Suwon (KR); DANIEL SODICKSON, Larchmont, NY (US); GRAHAM WIGGINS, New York, NY (US)

(21) Appl. No.: 14/686,127

(22) Filed: Apr. 14, 2015

Related U.S. Application Data
(60) Provisional application No. 61/979,130, filed on Apr. 14, 2014.

(51) Int. Cl. H01Q 9/26; G01R 33/561; G01R 33/36

(52) U.S. Cl. CPC H01Q 9/26; G01R 33/3628; G01R 33/5615

(57) ABSTRACT

Exemplary embodiments of the present disclosure include dipole arrangement, or an array of dipole arrangements which can include at least two poles extending in opposite direction from one another, each of the poles including capacitor and an inductor(s). A lattice balun can be located at a center gap between the poles, and can be a 50 ohm lattice balun. The capacitor(s) can be a 10.67 farad capacitor. The inductor can be a 26.7 Henry inductor. The length of each of the poles can depend on a wavelength of a magnetic field generated by the dipole arrangement, or it can depend on a distance from the dipole arrangement to a subject to be imaged.

### CROSS-REFERENCE TO RELATED APPLICATION(S)

This application relates to and claims priority from U.S. Patent Application No. 61/979,130, filed on Apr. 14, 2014, the entire disclosure of which is incorporated herein by reference.

### FIELD OF THE DISCLOSURE

The present disclosure relates generally to a medical imaging apparatus and method, and more specifically, to exemplary embodiments of a modified folded dipole antenna, methods and arrangements thereof.

### BACKGROUND INFORMATION

A linear dipole antenna can be analogous to an open bifurcated transmission line, which can effectively radiate radio frequency (“RF”) energy into the far field upon forming a sinusoidal current distribution on its leg. (See, e.g., Reference 1). The simple linear structure at resonance can facilitate standing wave current distribution, which can generate a transverse magnetic field that can be orthogonal to its axis. A radiative antenna design (see, e.g., Reference 2) can exhibit little B1+ twisting behavior which can have potential benefits for B1 mapping and pulse design. (See, e.g., Reference 3). It can include a low loss high dielectric material between the antenna and the object, which can mediate fields adaptively towards the imaging object, creating a far field condition. The dielectric material can also serve to capture local electric fields between the antenna and the conductive object. Based on electrodynamics suggesting favorable performance for electric dipoles at high field (see, e.g., Reference 4) several new antenna configurations have been introduced. A combination of linear dipoles and loops can offer signal-to-noise ratio (“SNR”) improvement of up to 23%, as compared to a loop only. (See, e.g., Reference 5). However, the linear dipole exhibits high sensitivity to loading due to the close proximity to the conductive object, which can hamper applications in subject dependent body imaging.

Despite the SNR benefits of high fields, body imaging at 7T can be challenging as major difficulties remain with strong B1 inhomogeneity, less penetration depth, complex Tx/Rx field patterns, and increased specific absorption rate (“SAR”). (See, e.g., Reference 8). Transuer electro-magnetic (“TEM”)/microstrip coils can be common in array design at ultra-high frequency (“UHF”), capturing local electric fields between two conductors but suffering from concomitant weak sensitivities deep in tissue due to the presence of the shielding effect of the ground plane. In regions of signal voids caused by either field twisting or destructive field interactions, accurate B1 maps can be difficult to obtain, limiting the effectiveness of B1 shimming and parallel transmit pulse design. Conventional loop designs can also exhibit significant field twisting behavior in conductive objects at high fields. (See, e.g., Reference 9).

Thus, it may be beneficial to provide an exemplary modified folded dipole antenna arrangement that (i) has less loading sensitivity, (ii) has favorable B1 patterns, and (iii) can be used at 7 Tesla, and which can overcome at least some of the deficiencies described herein above.

### SUMMARY OF EXEMPLARY EMBODIMENTS

Exemplary embodiments of the present disclosure include dipole arrangement, or an array of dipole arrangements which can include at least two poles extending in opposite direction from one another, each of the poles including capacitor and an inductor(s). A lattice balun can be located at a center gap between the poles, and can be a 50 ohm lattice balun. The capacitor(s) can be a 10.67 farad capacitor. The inductor can be a 26.7 Henry inductor. The size of the inductor(s) can be based on a phase discrepancy caused by the capacitor(s). The length of each of the poles can depend on a wavelength of a magnetic field generated by the dipole arrangement, or it can depend on a distance from the dipole arrangement to a subject to be imaged. The length of each pole can be about 15 centimeters. The capacitor(s) can be a distributed capacitor.

Exemplary embodiments of the present disclosure can also include, for example, a dipole array configuration, which can include plurality of dipole arrangements, with each of the dipole arrangements having at least two poles extending in opposite direction from one another, each of the poles including a capacitor(s) and an inductor(s). A lattice balun(s) can be located at a center gap between the poles, which can be a 50 ohm lattice balun. The capacitor(s) can be, e.g., a 10.67 farad capacitor, and the inductor(s) can be, e.g., a 26.7 Henry inductor. A size of the inductor(s) can be based on a phase discrepancy caused by the capacitor(s). A length of each of the poles can depend on a wavelength of a magnetic field generated by the dipole arrangement, and/or on a distance from the dipole arrangement to a subject to be imaged. For example, the dipole array configuration can include 8 dipole arrangements. According to some exemplary embodiments of the present disclosure, the capacitor(s) can be a distributed capacitor. Other capacitor(s) and/or inductor(s) can be used in according to various exemplary embodiments of the present disclosure.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1 is an exemplary illustration of an exemplary modified folded dipole antenna according to an exemplary embodiment of the present disclosure;

FIGS. 2A-2C are exemplary graphs illustrating dipole resonance shifts according to an exemplary embodiment of the present disclosure;

FIG. 3 is a an exemplary diagram illustrating capacitive reactance according to an exemplary embodiment of the present disclosure;

FIGS. 4A-4C are exemplary images illustrating axial flip angles according to an exemplary embodiment of the present disclosure;

FIG. 4D is an exemplary graph illustrating AP position as a function of the flip angle according to an exemplary embodiment of the present disclosure;

FIGS. 5A-5F are exemplary signal-to-noise ratio maps according to an exemplary embodiment of the present disclosure;

FIG. 6 is an exemplary illustration of an exemplary modified folded dipole array according to an exemplary embodiment of the present disclosure;

FIG. 7A is an image of the flip angle of an exemplary 8 channel modified folded dipole according to an exemplary embodiment of the present disclosure;

FIG. 7B is an image of the flip angle of an exemplary 8 channel loop according to an exemplary embodiment of the present disclosure;

FIG. 8A is an signal-to-noise ratio map for an exemplary 8 channel modified folded dipole according to an exemplary embodiment of the present disclosure;

FIG. 8B is an signal-to-noise ratio map of an exemplary 8 channel loop according to an exemplary embodiment of the present disclosure;

FIG. 9A is a set of maps of B1+ patterns of the exemplary modified folded dipole according to an exemplary embodiment of the present disclosure;

FIG. 9B is a set of maps of B1− patterns of the exemplary modified folded dipole according to an exemplary embodiment of the present disclosure;

FIGS. 10A and 10B are exemplary images of two-dimensional gradient echo axial images according to an exemplary embodiment of the present disclosure; and

FIG. 11 is a set of exemplary images of a plane localizer field of vision with a circular polarization shim set according to an exemplary embodiment of the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures or provided in the subsequent claims.

### DETAILED DESCRIPTION OF EXEMPLARY EMBODIMENTS

### Exemplary Modified Folded Dipole

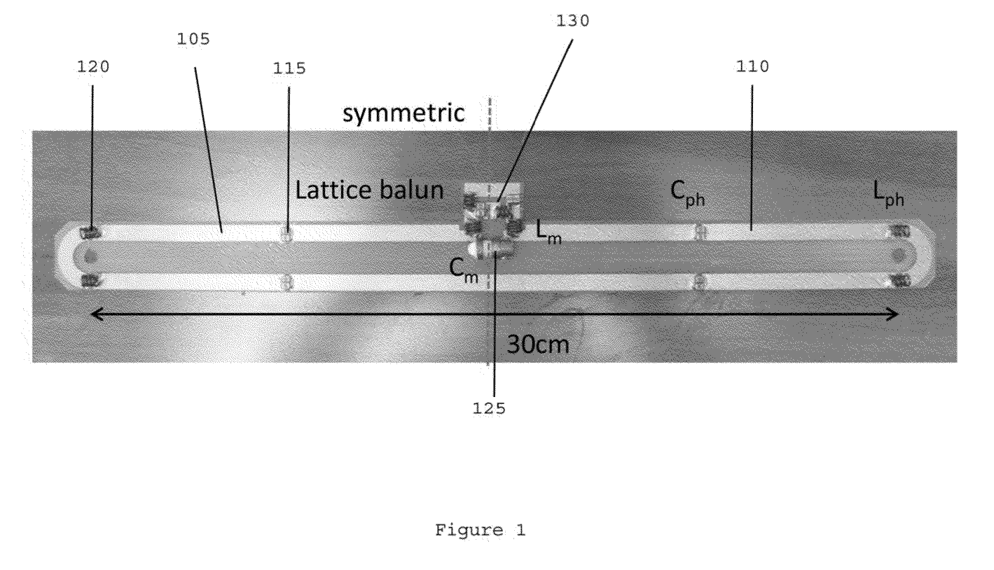

As shown in an exemplary illustration of FIG. 1, the exemplary modified folded dipole can include at least two poles (e.g., pole 105 and pole 110), which can extend in opposite direction from each other. The length of each pole 105 and 110 can be selected as a function of the wavelength of the magnetic field. The length of each pole 105 and 110 can also be selected based on a gap distance between the subject and the exemplary modified folded dipole. In one exemplary embodiment of the present disclosure, the length of poles 105 and 110 can each be about 15 cm, resulting in a modified dipole length of about 30 cm. However, it should be noted, that other suitable pole lengths, and other suitable combined dipole lengths, can be used. Each pole 105 and 110 can include one or more distributed capacitors 115 and one or more inductors 120. Capacitors 115 can be about a 10.67 pF capacitor, although larger or smaller capacitors can be used. Inductors 120 can be a 26.7 nH inductor, although larger or smaller inductors can be used, which can also be used to compensate for a phase discrepancy that can be caused by capacitors 115. Both capacitors 115 and inductors 120 can be used at 7 Tesla or below. A lattice balun 125 can be used to balance the signal at center gap 130, and can be a about 50 ohm lattice balun.

### Exemplary Method

An exemplary modified dipole antenna can be machined on a single cladding FR4 printed circuit board (“PCB”), and can have a size of about 32 cm long, about 1.8 cm leg spacing, and matched and tuned to about 50 ohms with the body size conductive phantom (e.g.

permittivity of about 60 and a conductivity of about 0.7 [S/m]). (See e.g., FIG. 1). Another modified folded dipole of about 35 cm length can be prepared, for example, only for the antenna gap impedance measurement. The antenna was matched and tuned on top of the phantom in vertical position to minimize electric coupling between the antenna and the phantom. The matching network can include the balanced L-section and the about 50 ohm lattice balun, implemented at the center gap to obtain symmetric currents on its bifurcated legs. The lumped components placed symmetrically along the legs can be four identical capacitors that can be used to capture local electric fields and four phase-compensating inductors to sustain the half wave standing wave currents.

For a determination of the antenna sensitivity, for example, loading changes of the resonant frequency shift can be quantified by s11 measurements as the function of air gap between the antenna and the phantom (e.g. H0:1.6 cm, H1:2.8 cm, H2:4 cm). This can be compared to two reference coils, the about 12 cm diameter loop and the linear dipole of about 37 cm. The antenna gap impedance of two elements (e.g. an about 37 cm dipole and an about 35 cm modified folded dipole) was also measured to determine their resistance/reactance changes by the air gap. The axial flip angle (“FA”) image of the modified folded dipole was obtained using the pre-saturation based B1 map (see, e.g., Reference 6), and compared to the reference coils at the same Tx reference. The 3 plane SNR images of the modified folded dipole and the loop were obtained by acquiring two-dimensional (“2D”) gradient echo (“GRE”) signal and separate noise images at the same setup.

### Exemplary Results

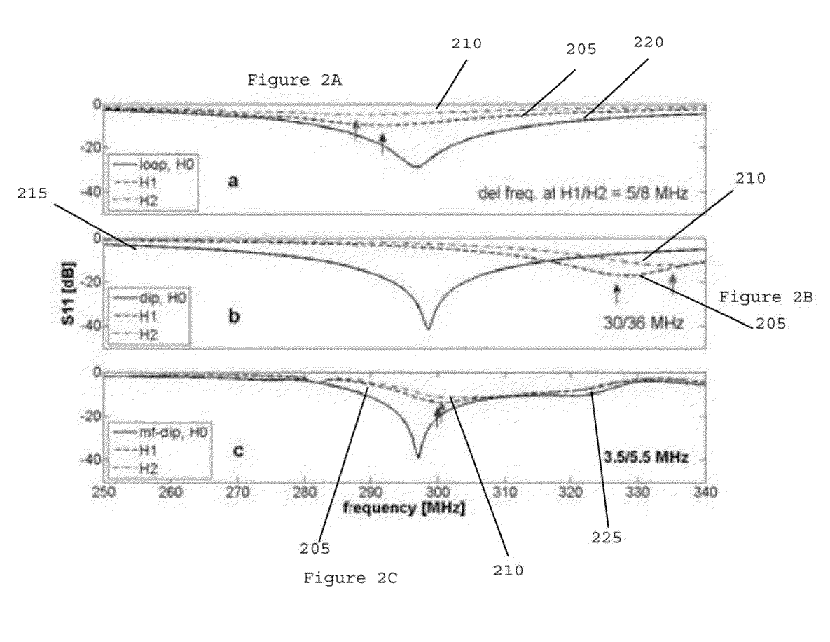

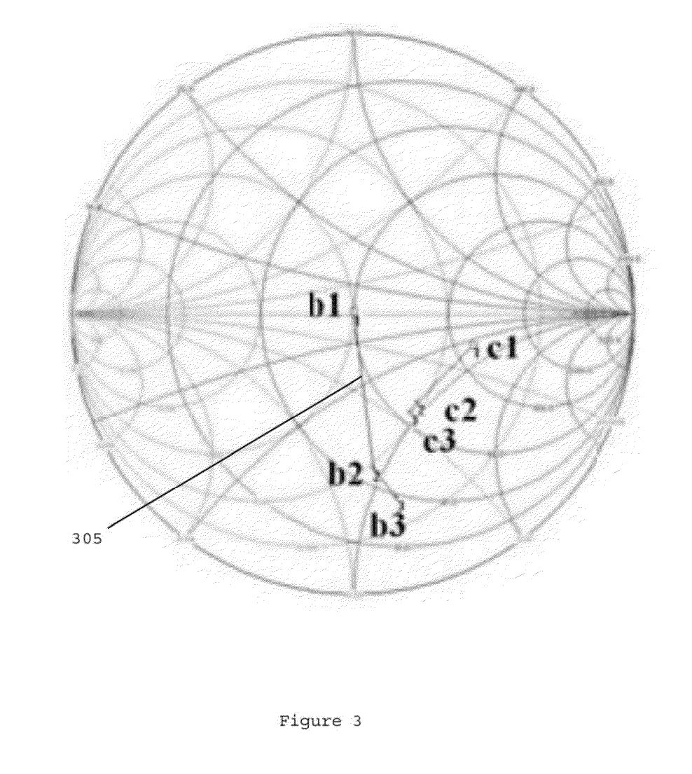

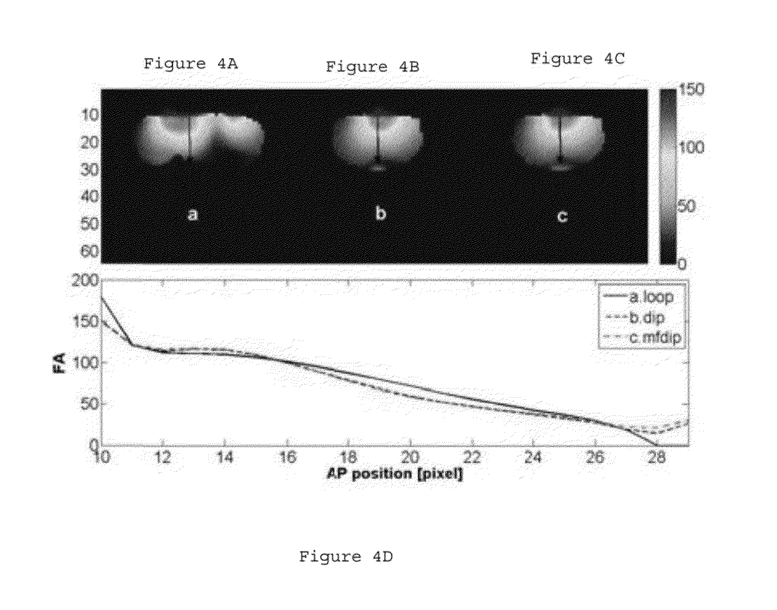

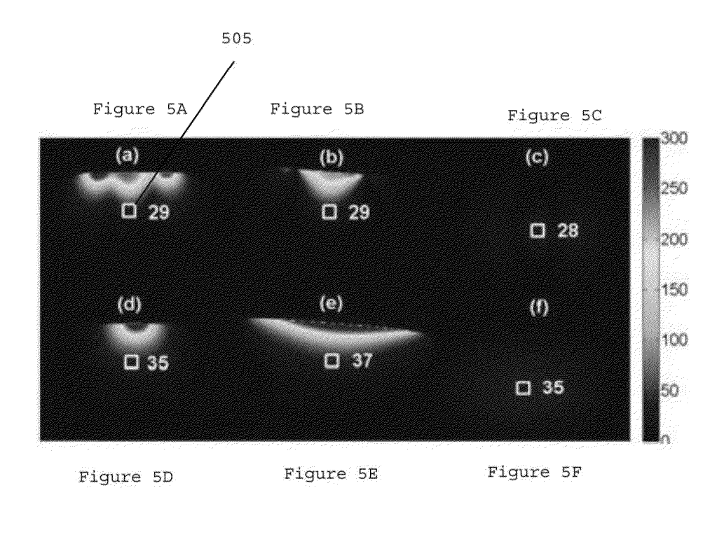

FIGS. 2A-2C show exemplary graphs illustrating H1 (e.g., element 205) and H2 (e.g., element 210). The linear dipole can exhibit strong resonance shifts (e.g. 30/36 MHz) upwards at H1/H2 (e.g. FIG. 2B) from the reference at dip H0 (e.g., element 215), as the effective antenna length can be shortened due to the capacitive reactance (e.g. FIG. 3 elements b1, b2, and b3). In contrast, the loop HO (e.g., element 220) can show relatively less shifts (e.g. ⅝ MHz) downwards at H1/H2, which can be attributable to inductive screening. (See e.g., FIG. 2A). The exemplary modified folded dipole H0 (e.g., element 225) can reduce the resonance shifts further (e.g. 3.5/5.5 MHz in FIG. 2C as shown against the air gap change). Note that the input reactance change of the modified folded dipole at H0, H1 and H2 can be roughly constant (e.g. FIG. 3 elements c1, c2, and c3), which can illustrate that the antenna resonance can sustain against the air gap changes, however, the matching can be affected as seen by the resistance variations. The axial FA distribution illustrates that the modified folded dipole can be similar or almost identical to the linear dipole, and both can be comparable to the loop at the same Tx reference; noting that the FA profile of the loop was taken at the maximum B1+ sensitivity (element 305 of FIG. 3). In exemplary images of FIGS. 5A-5F, on the sampled locations (e.g., rectangles 505), the modified folded dipole shows approximately 20 to 28% higher SNR compared to the loop at the same distance from the surface. With respect to geometrical difference of two elements (e.g. loop 12 cm and modified folded dipole 32 cm), the modified folded dipole shows the wider sagital FOV, and monotonic field patterns in all planes, whereas the single loop shows wider axial FOV with more dynamic patterns. FIGS. 4A-4C are exemplary images illustrating axial flip angles according to an exemplary embodiment of the present disclosure. For example, FIG. 4A illustrates an axial flip angle of a loop, FIG. 4B illustrates an axial flip angle of a dip and FIG. 4C illustrates an axial flip angle of the exemplary modified folded dipole. FIG. 4D is an exemplary graph illustrating AP position as a function of the flip angle.

### Exemplary Discussion

The reactance of the linear dipole antenna can be strongly perturbed by the proximity of the conducting object through the parasitic capacitance between them, challenging reliable tune and match with varying imaging subjects. The distributed lumped components of the exemplary modified folded dipole can serve to sustain the antenna reactance in the presence of loading variations, without the aid of a mediating material, which can be favorable to the body array construction at UHF. The excitation efficiency between the loop and the dipole/modified folded dipole can be comparable at their own maximum sensitivity lines. For example, the higher SNR with the modified folded dipole can be attributed to the degree of B1+ and sensitivity coherence. Thus, the sampled SNR location of the loop may not be at the maximum B1+ or B1− regions due to the field twisting behavior. (See, e.g., Reference 7). The generous sagital FOV of the exemplary modified folded dipole can be beneficial to body imaging, such as, thoracic lumbar spine imaging with benign B1 field twisting behavior. With respect to SAR, the temperature increment by the exemplary modified folded dipole was measured to be comparable to the loop. Therefore, the exemplary antenna design can be beneficial in UHF body imaging.

### Exemplary Modified Folded Dipole Array

### Exemplary Method

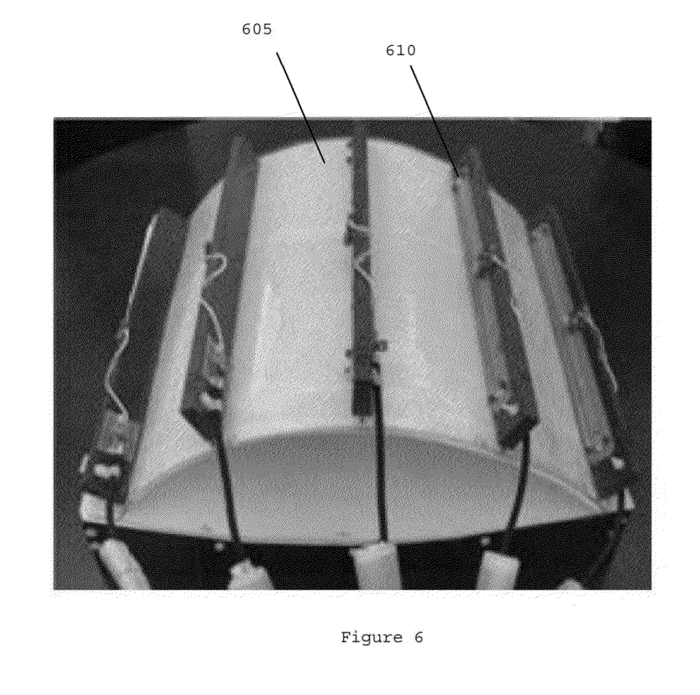

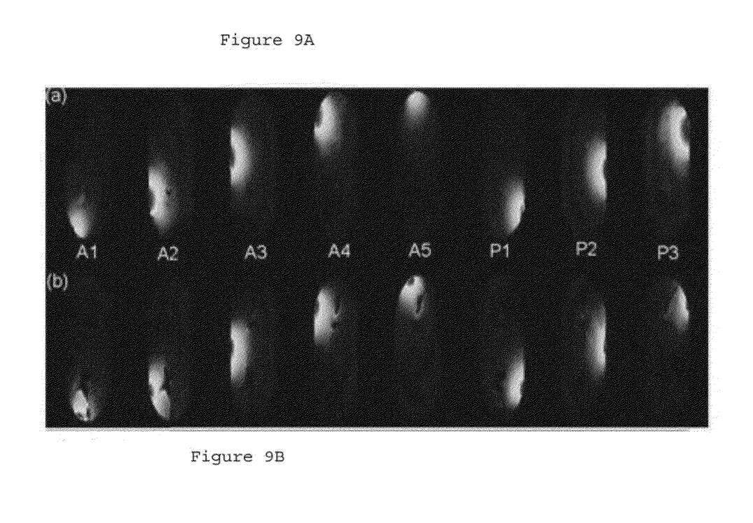

As shown in FIG. 6, the exemplary modified folded dipole array arrangement 605 can include, for example, 8 elements (e.g., modified folded dipoles 610) arranged in three posterior elements under the PVC frame with about a 40 cm length and about a 45 cm width, and five anterior elements on a flexible acrylic plate to accommodate various body shapes. Elements 610 can be, for example, about 32 cm long, positioned about 11 cm apart, and all reasonably matched (e.g. S11 below −20 dB) and isolated (e.g. S21 below −18 dB) in the presence of the conductive object (e.g. body size agar gel phantom, permittivity=77, conductivity=0.6 [S/m]). For imaging experiments, the array was connected to an in-house TR switch box through two cable traps per element to suppress common mode currents. The array was interfaced to a 7T 8ch pTx system (e.g. Siemens, Magnetom) with capability of about 1 kW maximum peak power per channel. The bench mark coil, 8ch loop array with 2ch Tx/Rx & 8ch Rx was used for the efficiency comparison. (See, e.g., Reference 11). As a Tx performance metric, the FA images on the axial center slice were obtained at the maximum available Tx reference voltage for both coils using the pre-saturation based B1 map. (See, e.g., Reference 6). Phases to the 8 elements were specified such that they produce circular polarization at the center of the phantom, whereas the 2ch loops were optimally positioned to get the constructive B1 at the center with power from the single channel system split and phased by 180 degrees. (See, e.g., Reference 11). SNR maps for root sum of squares reconstruction were generated by acquiring 2D GRE images both with and without RF excitation. These maps were normalized for excitation flip angle distribution by dividing by the sine of the flip angle at each pixel. The individual B1+ maps (e.g. FIG. 9A) were calculated based on each FA distribution, and normalized by its maximum, whereas the B1− maps were obtained by normalizing each 2D GRE image by the sine of the excitation flip angle at each pixel (e.g. FIG. 9B). After safety evaluations, in-vivo 2D GRE body images using the 3 spoke pTx pulses (e.g. based on DREAM B1 map sequence (see, e.g., Reference 14)) were attempted, and compared to conventional circularly polarized excitation (e.g. 256×256, TR/TE:20/4 ms, BW: 1028 Hz/pix, Slice thick: 5 mm, FOV280 mm). For the exemplary spoke pulse calculations, two separate B1 maps were obtained with the circular polarization (“CP”) and gradient mode (“GM”) shim sets that compensate null regions with each other due to the orthogonal mode relations, enabling more reliable B1 maps for each channel.

### Exemplary Results

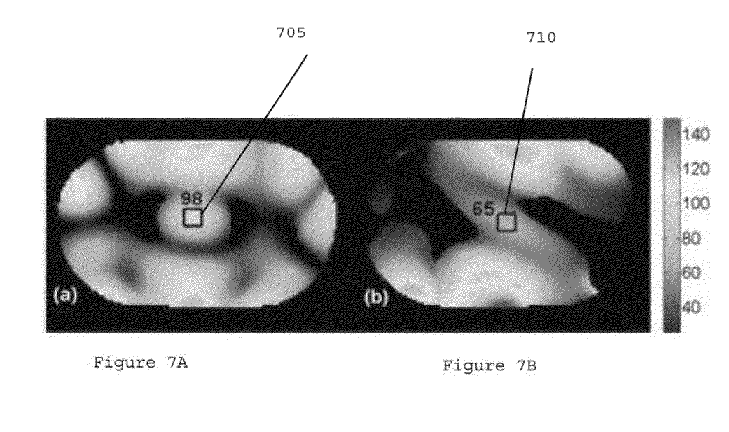

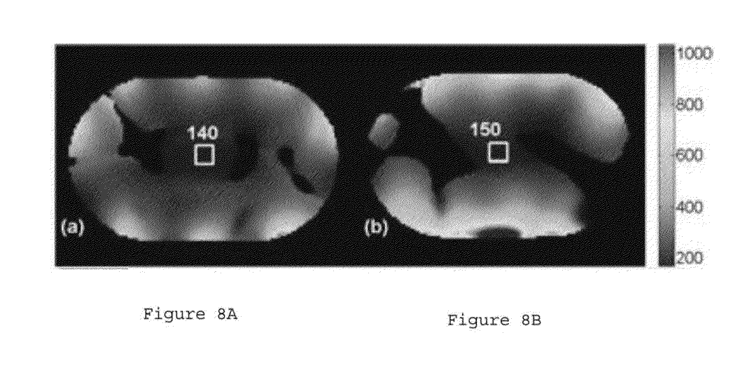

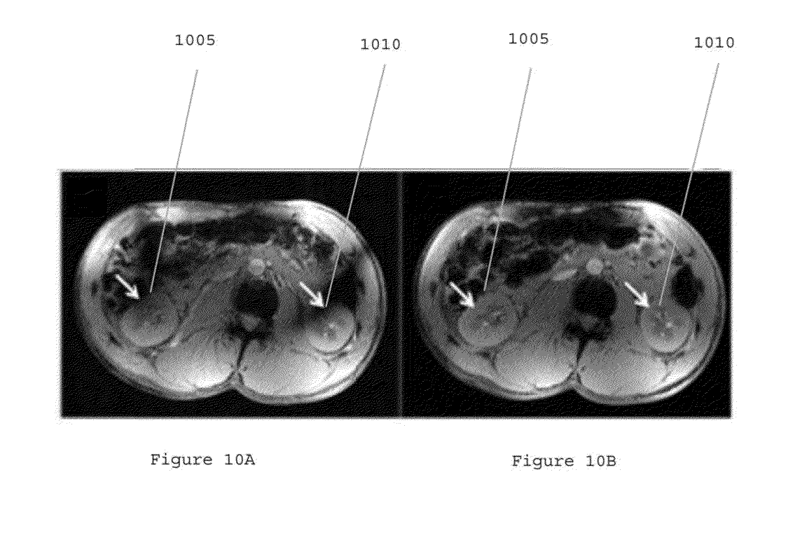

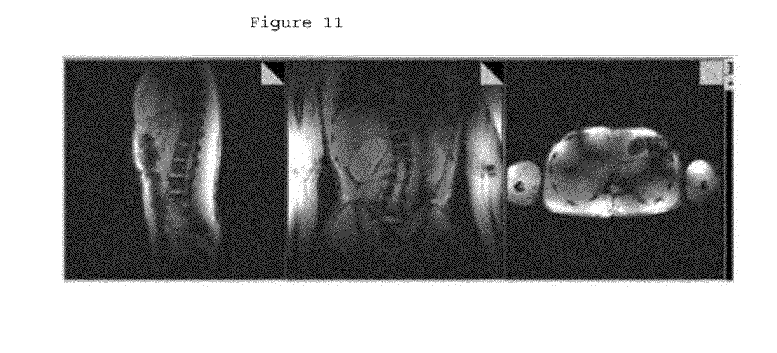

At the maximum Tx power available, the exemplary modified folded dipole array arrangement can provide about a 98 degree FA (e.g., area 705 in the exemplary image of FIG. 7A) in the centric region, compared to the about 65 degree FA (e.g. area 710 in the exemplary image of FIG. 7B) using the optimized 2 loop transmit configuration. Assuming comparable total excitation power between two cases, the exemplary modified folded dipole array arrangement can exhibit approximately 50% improvement in Tx performance. On the receive side, the Bch loop shows 7% better normalized SNR performance at the center (e.g. see area 150 in FIG. 8B), compared to the modified folded dipole array (e.g. area 140 in FIG. 8A), also exhibiting higher signals in the periphery (e.g. exemplary images of FIGS. 8A and 8B). Individual B1+ and B1-maps of the array are shown in FIGS. 9A and 9B, respectively, illustrating benign field twisting and monotonic field decay from the antenna. The uniform excitation using the 3 spoke pTx pulses, compared to the CP local shim set, eliminates dark bands around both kidneys (e.g., areas 1005 and 1010). (See, e.g., FIGS. 10A and 10B). The 3 plane localizer images with the CP shim set can demonstrate the broad FOV (e.g. about 450×450) of the array suitable for body applications. FIG. 11 is a set of exemplary images of a plane localizer field of vision 450 with a circular polarization shim set according to an exemplary embodiment of the present disclosure.

### Further Exemplary Discussion

Higher FA achieved using the exemplary modified folded dipole array arrangement can be attributed not only to the benefits of the local phase shim, but also to the in-phase current distribution of the exemplary modified folded dipole structure, compared to a shielded stripline element where the current on the shield can oppose the current on the element, contributing to enhanced sensitivity with depth. In addition, the unidirectional currents on its bifurcated legs can contribute to the benign field twisting as a contrast to the TEM or the loop. The slight SNR degradation of the exemplary modified folded dipole can be caused by the additional loss of the lumped inductors that can be replaced by a distributed antenna layout design. Initial assessment of the uniform excitation, using the tailored pTx pulse, illustrates improvement in B1 homogeneity effectively, due to an improved exemplary B1 map acquisition method.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification, drawings and claims thereof, can be used synonymously in certain instances, including, but not limited to, e.g., data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

### EXEMPLARY REFERENCES

The following references are hereby incorporated by reference in their entirety.
[1] Ant. Theo. & Des., 2nd Ed., Stutzman
[2] MRM2011, 66(5):1488-97.
[3] ISMRM 20(2012), p 307
[4] MRM2012, 68(1):286-304
[5] ISMRM 20(2012) p 541
[6] ISMRM 16(2008) p 1247
[7] ISMRM 20(2012) p 2996
[8] MRM 2012 67(4): 954-964
[9] ISMRM 20(2012) p 2996
[10] ISMRM 21(2013) submitted
[11] ISMRM 20(2012) p 2782
[12] ISMRM 16(2008) p 1247
[13] MRM 2005 54(6):1439-1447
[14] MRM 68(2012):1517-1526

What is claimed is:

1. A dipole arrangement, comprising:
at least two poles extending in opposite direction from one another, each of the poles including at least one capacitor and at least one inductor.

2. The dipole arrangement of claim 1, further comprising at least one lattice balun located at a center gap between the poles.

3. The dipole arrangement of claim 2, wherein the at least one lattice balun is a 50 ohm lattice balun.

4. The dipole arrangement of claim 1, wherein the at least one capacitor is a 10.67 farad capacitor.

5. The dipole arrangement of claim 1, wherein the at least one inductor is a 26.7 Henry inductor.

6. The dipole arrangement of claim 1, wherein a size of the at least one inductor is based on a phase discrepancy caused by the at least one capacitor.

7. The dipole arrangement of claim 1, wherein a length of each of the poles depends on a wavelength of a magnetic field generated by the dipole arrangement.

8. The dipole arrangement of claim 1, wherein a length of each of the poles depends on a distance from the dipole arrangement to a subject to be imaged.

9. The dipole arrangement of claim 1, wherein a length of each pole is about 15 centimeters.

10. The dipole arrangement of claim 1, wherein the at least one capacitor is a distributed capacitor.

11. A dipole array configuration, comprising:
a plurality of dipole arrangements, each of the dipole arrangements comprising:
at least two poles extending in opposite direction from one another, each of the poles including at least one capacitor and at least one inductor.

12. The dipole array configuration of claim 11, further comprising at least one lattice balun located at a center gap between the poles.

13. The dipole array configuration of claim 12, wherein the at least one lattice balun is a 50 ohm lattice balun.

14. The dipole array configuration of claim 11, wherein the at least one capacitor is a 10.67 farad capacitor.

15. The dipole array configuration of claim 11, wherein the at least one inductor is a 26.7 Henry inductor.

16. The dipole array configuration of claim 11, wherein a size of the at least one inductor is based on a phase discrepancy caused by the at least one capacitor.

17. The dipole array configuration of claim 11, wherein a length of each of the poles depends on a wavelength of a magnetic field generated by the dipole arrangement.

18. The dipole array configuration of claim 11, wherein a length of each of the poles is depends on a distance from the dipole arrangement to a subject to be imaged.

19. The dipole array configuration of claim 11, wherein the plurality of dipole arrangements includes 8 dipole arrangements.

20. The dipole configuration of claim 11, wherein the at least one capacitor is a distributed capacitor.
